(19) United States
(12) Patent Application Publication
(10) Pub. No.: US 2026/0013099 A1
(43) Pub. Date: Jan. 8, 2026

(54) SEMICONDUCTOR DEVICE AND MANUFACTURING METHOD THEREOF

(71) Applicant: NANYA TECHNOLOGY CORPORATION, New Taipei City (TW)

(72) Inventor: Ying-Cheng CHUANG, New Taipei City (TW)

(21) Appl. No.: 18/765,329

(22) Filed: Jul. 8, 2024

(51) Int. Cl. H10B 12/00

(52) U.S. Cl. CPC H10B 12/053; H10B 12/34

(57) ABSTRACT

In accordance with an aspect of the present disclosure, a manufacturing method of a semiconductor device is provided. The method includes following steps. A first trench in an active region of a substrate and forming a second trench in an isolation region of the substrate are formed, wherein a second depth of the second trench is deeper than a first depth of the first trench. A bottom conductive layer is formed in the first trench and the second trench. A top conductive layer is formed on the bottom conductive layer. A photoresist layer in the first trench and on a top surface of the substrate is formed, wherein the top conductive layer in the second trench is exposed. The top conductive layer in the second trench is removed. A capping layer is formed to fill the first trench and the second trench.

### FIELD OF INVENTION

The present disclosure relates to a semiconductor device and manufacturing method thereof.

### DESCRIPTION OF RELATED ART

In recent decades, demand to storage capability has increased as electronic products continue to improve. In order to increase storage capability of a memory device (e.g., a DRAM device), more memory cells are integrated in the memory device. As the integration level increases, semiconductor structures may cause gate induced drain leakage (GIDL).

### SUMMARY

In accordance with an aspect of the present disclosure, a manufacturing method of a semiconductor device is provided. The method includes following steps. A first trench in an active region of a substrate and forming a second trench in an isolation region of the substrate are formed, wherein a second depth of the second trench is deeper than a first depth of the first trench. A bottom conductive layer is formed in the first trench and the second trench. A top conductive layer is formed on the bottom conductive layer. A photoresist layer in the first trench and on a top surface of the substrate is formed, wherein the top conductive layer in the second trench is exposed. The top conductive layer in the second trench is removed. A capping layer is formed to fill the first trench and the second trench.

According to some embodiments of the present disclosure, wherein prior to forming the bottom conductive layer further includes forming a barrier layer on a first sidewall of the first trench.

According to some embodiments of the present disclosure, wherein subsequent to forming the barrier layer further comprises forming an oxidation layer on the barrier layer of the first trench and a second sidewall of the second trench.

According to some embodiments of the present disclosure, wherein prior to forming the top conductive layer further comprises cleaning a portion of the oxidation layer on the first sidewall of the first trench and the second sidewall of the second trench; and forming a bottom dielectric layer on the bottom conductive layer, the first sidewall of the first trench and the second sidewall of the second trench.

According to some embodiments of the present disclosure, wherein prior to forming the capping layer further comprises forming a top dielectric layer on the top conductive layer, the first sidewall of the first trench and the second sidewall of the second trench.

According to some embodiments of the present disclosure, wherein the photoresist layer is formed by a pitch doubling process.

According to some embodiments of the present disclosure, wherein prior to forming the first trench and the second trench further comprises forming a cover layer on the substrate.

According to some embodiments of the present disclosure, wherein prior to forming the capping layer further comprises stripping the photoresist layer to expose the top conductive layer in the first trench.

In accordance with an aspect of the present disclosure, a semiconductor device is provided. The semiconductor device includes a substrate, a first word line structure, a second word line structure, and a capping layer. The substrate has an active region and an isolation region. The first word line structure is disposed in the active region. The second word line structure is disposed in the isolation region. The capping layer is disposed on the first word line structure, second word line structure and the substrate. A bottom surface of the first word line structure is higher than a bottom surface of the second word line structure. A top surface of the first word line structure is higher than a top surface of the second word line structure.

According to some embodiments of the present disclosure, wherein the first word line structure comprises a bottom conductive layer, a top conductive layer, and a bottom dielectric layer. The top conductive layer is on the bottom conductive layer. The bottom dielectric layer is between the bottom conductive layer and the top conductive layer.

According to some embodiments of the present disclosure, wherein the second word line structure comprises a bottom conductive layer.

According to some embodiments of the present disclosure, wherein a top surface of the bottom conductive layer of the first word line structure and a top surface of the bottom conductive layer of the second word line structure are on the same level.

According to some embodiments of the present disclosure, the semiconductor device further includes a top dielectric layer between the top conductive layer of the first word line structure and the capping layer, and between the bottom conductive layer of the second word line structure and the capping layer, respectively.

According to some embodiments of the present disclosure, the semiconductor device further includes an oxidation layer between the substrate and the bottom conductive layer of the first word line structure, and between the substrate and the bottom conductive layer of the second word line structure.

According to some embodiments of the present disclosure, the semiconductor device further includes a barrier layer between the bottom conductive layer of the first word line structure and the oxidation layer.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a cross-sectional view schematic diagram of a semiconductor device, in accordance with some embodiments;

FIG. 2 is a cross-sectional view schematic diagram of a semiconductor device after forming oxidation layer, in accordance with some embodiments;

FIG. 3 is a cross-sectional view schematic diagram of a semiconductor device after forming a bottom conductive layer, in accordance with some embodiments;

FIG. 4 is an top view schematic diagram of FIG. 3, in accordance with some embodiments;

FIG. 5 is a cross-sectional view schematic diagram of a semiconductor device after cleaning a portion of the oxidation layer, in accordance with some embodiments;

FIG. 6 is a cross-sectional view schematic diagram of a semiconductor device after forming a bottom dielectric layer, in accordance with some embodiments;

FIG. 7 is a cross-sectional view schematic diagram of a semiconductor device after forming a top conductive layer, in accordance with some embodiments;

FIG. 8 is an top view schematic diagram of FIG. 7, in accordance with some embodiments;

FIG. 9 is a cross-sectional view schematic diagram of a semiconductor device after forming a photoresist layer, in accordance with some embodiments;

FIG. 10 is an top view schematic diagram of FIG. 9, in accordance with some embodiments;

FIG. 11 is a cross-sectional view schematic diagram of a semiconductor device after removing the top conductive layer in the second trench, in accordance with some embodiments;

FIG. 12 is an top view schematic diagram of FIG. 11, in accordance with some embodiments; and

FIG. 13 is a cross-sectional view schematic diagram of a semiconductor device after forming a top dielectric layer and a capping layer.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

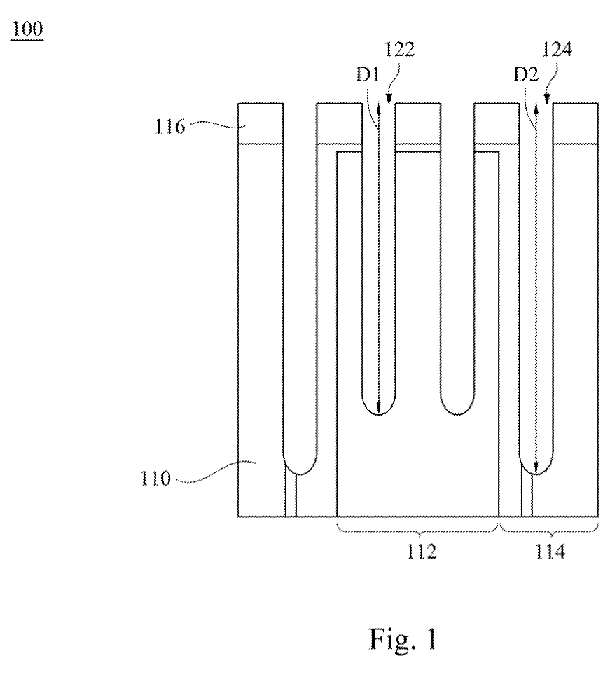

FIG. 1 is a cross-sectional view schematic diagram of a semiconductor device 100, in accordance with some embodiments. Referring to FIG. 1, the semiconductor device 100 includes a substrate 110, wherein the substrate 110 having an active region 112 and an isolation region 114. In some embodiments, the substrate 110 may be, for example, a silicon (Si) substrate. Alternatively, the substrate 110 can is a Si substrate and is doped with other IV-IV, III-V or II-VI semiconductor materials. In some other embodiments, the substrate 110 may include a layered semiconductor such as silicon/silicon germanium, silicon-on-insulator, or silicon germanium-on-insulator.

In some embodiments, the active region 112 may be doped with an N-type dopant such as phosphorus (P), arsenic (As), or antimony (Sb). In some other embodiments, the active region 112 may be doped with a P-type dopant such as boron (B) or indium (In). In some embodiments, the substrate 110 may be or include an unimplanted area. In some embodiments, the active region 112 may have a higher doping concentration than the substrate 110. In some embodiments, the isolation region 114 can be shallow trench isolation (STI) region. The isolation region 114 may include silicon oxide, silicon nitride, silicon oxynitride (SiON), SiOCN, SiCN, fluorine-doped silicate glass (FSG), a low-k dielectric material, or any suitable dielectric material. In some embodiments, a cover layer 116 is formed on the substrate 110. The cover layer 116 may include nitride, for example silicon nitride (SiN).

Referring to FIG. 1, a first trench 122 may be formed in the active region 112 of the substrate 110, and a second trench 124 may be formed in the isolation region 114 of the substrate 110. The first trench 122 has a first depth D1 from a top surface of the cover layer 116 to a bottom surface of the first trench 122. The second trench 124 has a second depth D2 from a top surface of the cover layer 116 to a bottom surface of the second trench T2. As shown, the second depth D2 is deeper than the first depth D1. The first trench 122 and the second trench 124 may be formed by one or more etching process.

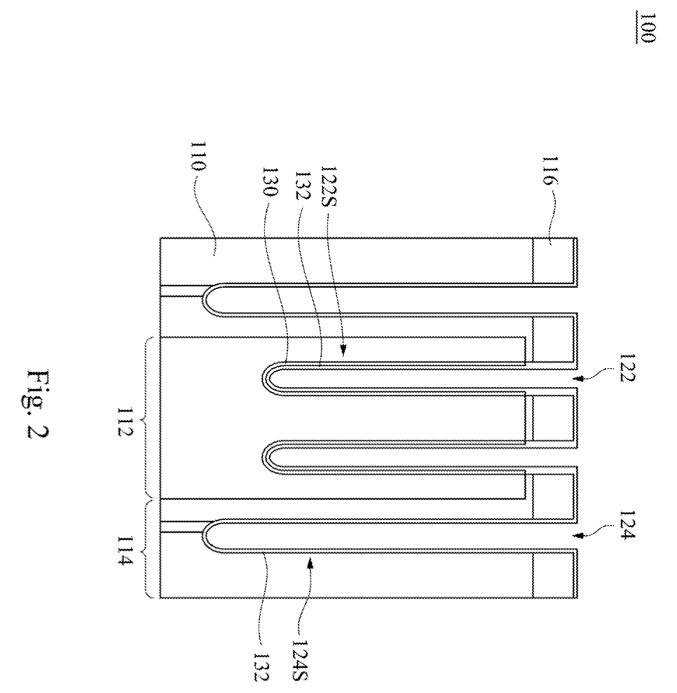

Referring to FIG. 2, a barrier layer 130 may be formed in the first sidewall 122S of the first trench 122. The barrier layer 130 may include oxide, and can be formed by in-situ steam generation (ISSG) process. Then, an oxidation layer 132 may be formed on the barrier layer 130 in the first trench 122, and on the second sidewall 124S of the second trench 124. The oxidation layer 132 may include a different oxide than the barrier layer 130. The oxidation layer 132 can be formed by atomic layer deposition (ALD) process.

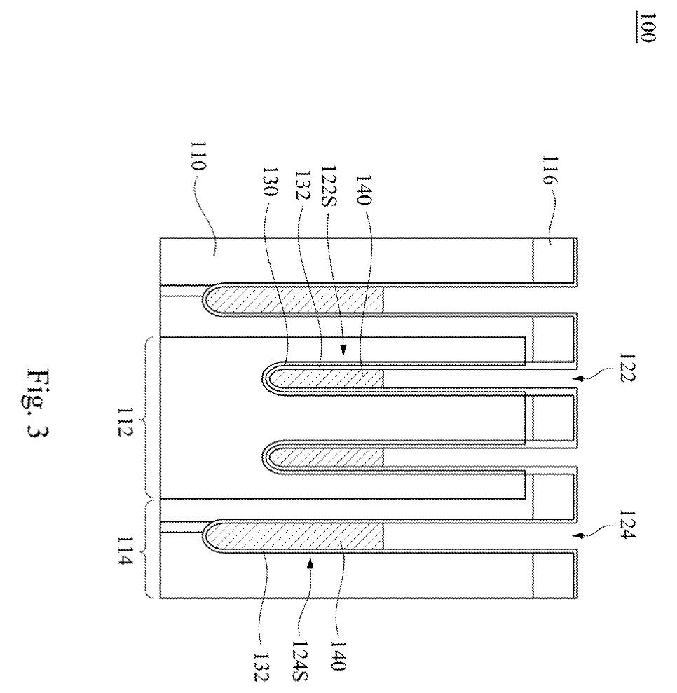

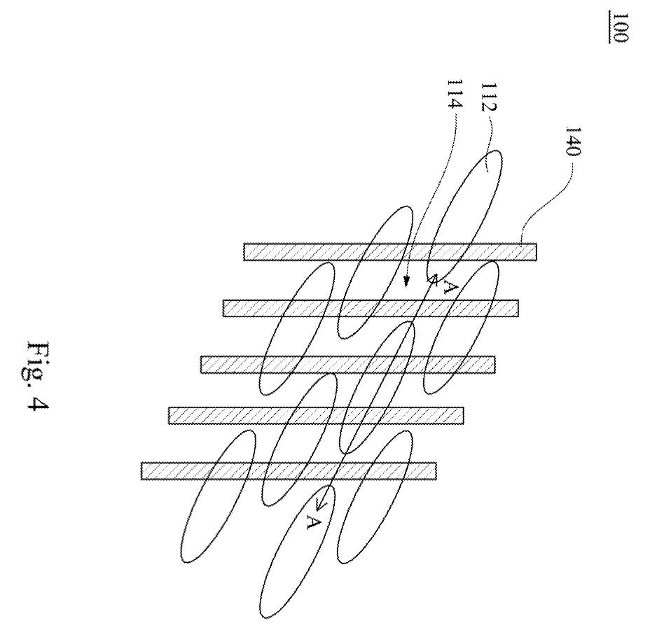

Referring to FIG. 3 and FIG. 4, FIG. 3 is a cross-sectional view schematic diagram along the A-A line in FIG. 4. In other words, FIG. 4 is a top view schematic diagram of FIG. 3. A bottom conductive layer 140 is formed in the bottom portion of the first trench 122 and the second trench 124, respectively. The bottom conductive layer 140 is formed by suitable deposition process, for example, chemical vapor deposition (CVD), atomic layer deposition (ALD), or physical vapor deposition (PVD). Then, a portion of the bottom conductive layer 140 is removed by a suitable etching process such that the top surface of the bottom conductive layer 140 is lower than the top surface of the cover layer 116. The top surface of the bottom conductive layer 140 in the first trench 122 and the top surface of the bottom conductive layer 140 in the second trench 124 are basically in same level. In some embodiments, the material of the bottom conductive layer 140 can be metal nitride such as TiN.

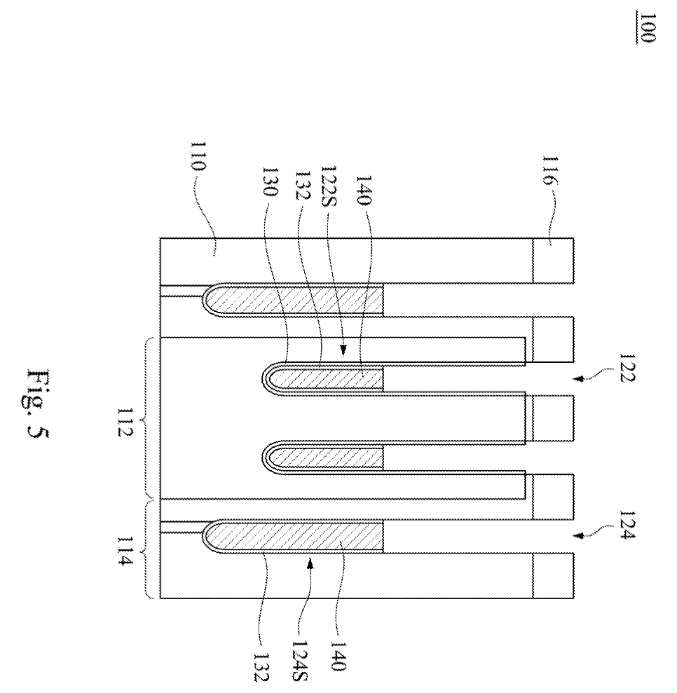

Referring to FIG. 5, a portion of the oxidation layer 132 on the first sidewall 122S of the first trench 122 and the second sidewall 124S of the second trench 124 are cleaned. The oxidation layer 132 may be removed by a suitable etching process, for example, a wet etching process. After cleaning a portion of the oxidation layer 132, the barrier layer 130 in the first trench 122 is exposed, and the second sidewall 124S of the second trench 124 is exposed.

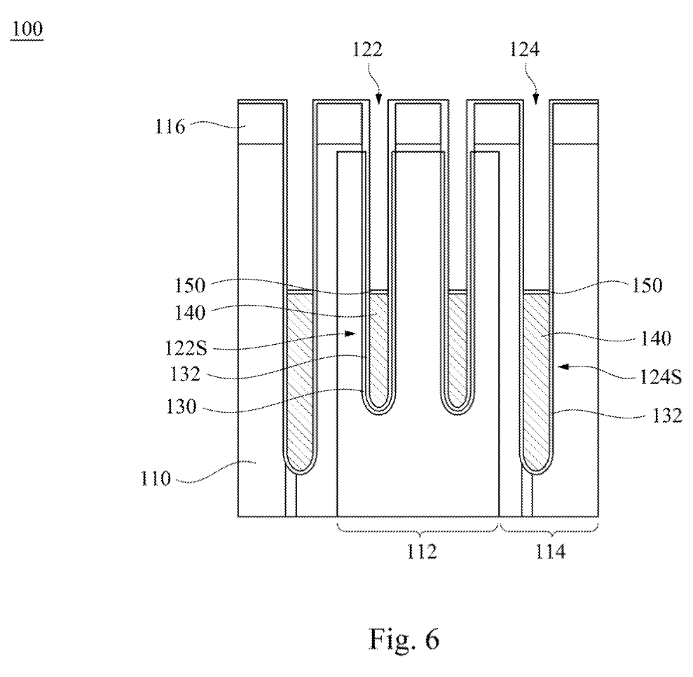

Referring to FIG. 6, a bottom dielectric layer 150 is formed on the bottom conductive layer 140 in the first trench 122 and the second trench 124, respectively. The bottom dielectric layer 150 may also cover the first sidewall 122S of the first trench 122, the second sidewall 124S of the second trench 124, and the top surface of the cover layer 116. The bottom dielectric layer 150 may be formed by atomic layer deposition (ALD) process. The bottom dielectric layer 150 may include oxide. In some embodiments, the bottom dielectric layer 150 may include same material with the oxidation layer 132.

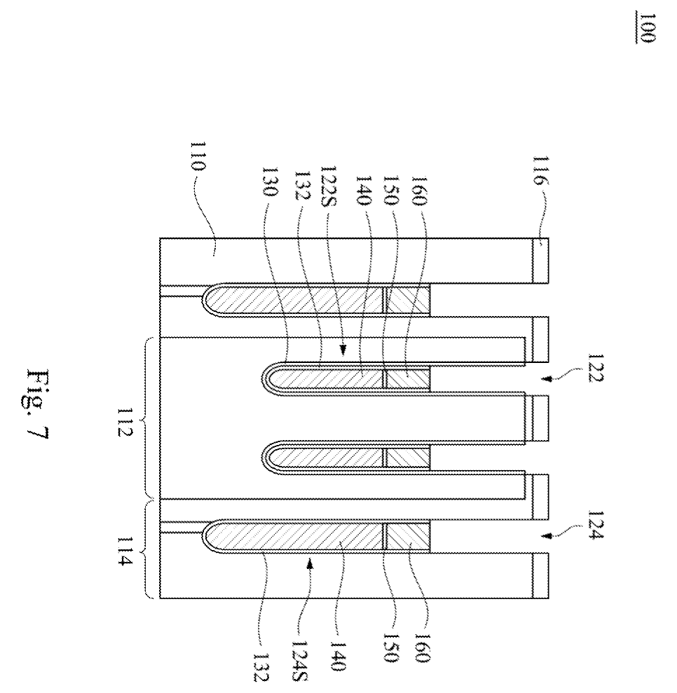

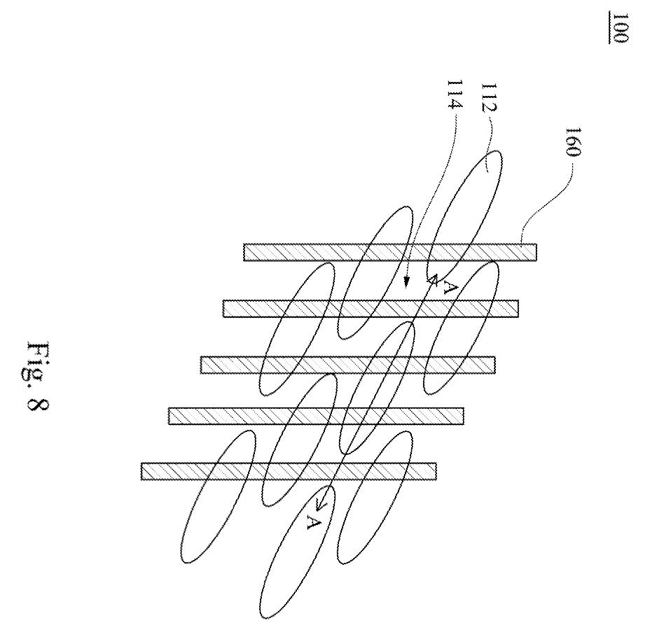

Referring to FIG. 7 and FIG. 8, FIG. 7 is a cross-sectional view schematic diagram along the A-A line in FIG. 8. In other words, FIG. 8 is a top view schematic diagram of FIG. 7. A top conductive layer 160 is formed on the bottom dielectric layer. The top conductive layer 160 is formed by suitable deposition process, for example, chemical vapor deposition (CVD), atomic layer deposition (ALD), or physical vapor deposition (PVD). Then, a portion of the top conductive layer 160 is removed by a suitable etching process such that the top surface of the top conductive layer 160 is lower than the top surface of the cover layer 116. In some embodiments, a portion of the cover layer 116 and a portion of the bottom dielectric layer 150 are removed when removing a portion of the top conductive layer 160. The top surface of the top conductive layer 160 in the first trench 122 and the top surface of the top conductive layer 160 in the second trench 124 are basically in same level. In some embodiments, the material of the bottom conductive layer 140 can be poly silicon.

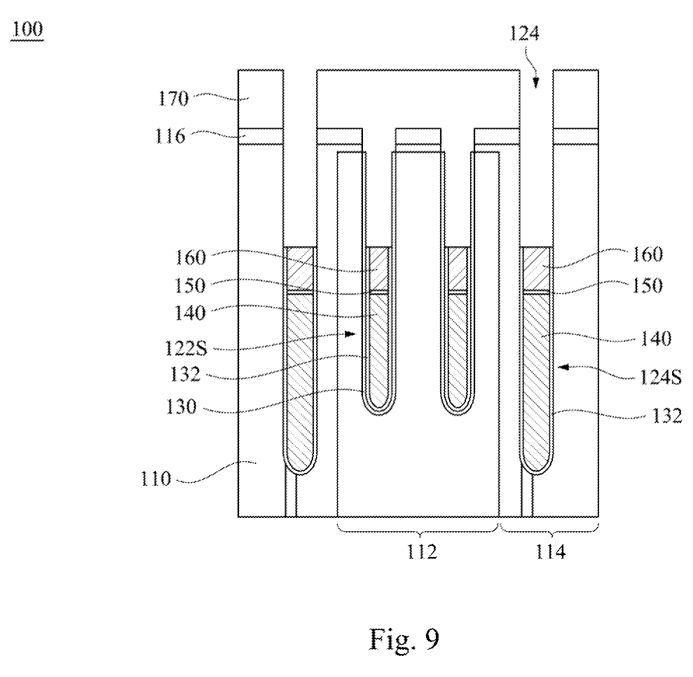

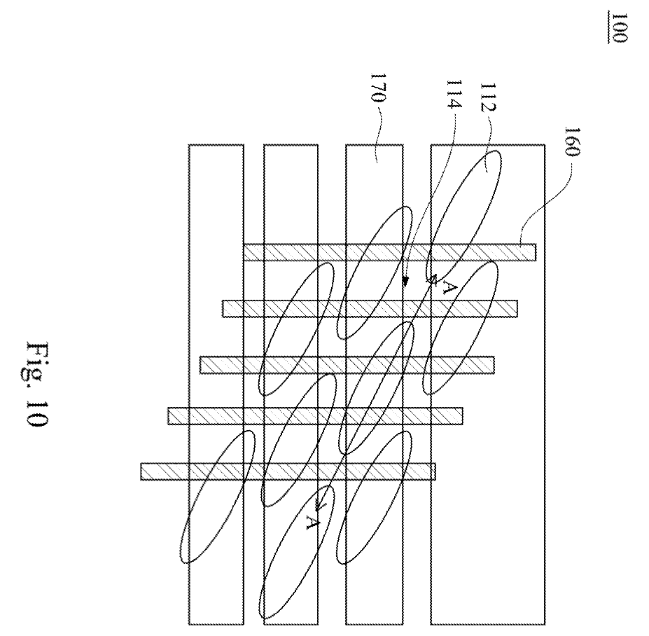

Referring to FIG. 9 and FIG. 10, FIG. 9 is a cross-sectional view schematic diagram along the A-A line in FIG. 10. In other words, FIG. 10 is a top view schematic diagram of FIG. 9. A photoresist layer 170 is formed in the first trench 122 and on a top surface of the substrate 110. The top conductive layer 160 in the second trench 124 is exposed after forming the photoresist layer 170. The photoresist layer may be formed by a pitch doubling process to expose the top conductive layer 160 in the second trench 124 accurately. As shown in FIG. 10, the active region 112 is covered by the photoresist layer 170, and the isolation region 114 is exposed by the photoresist layer 170.

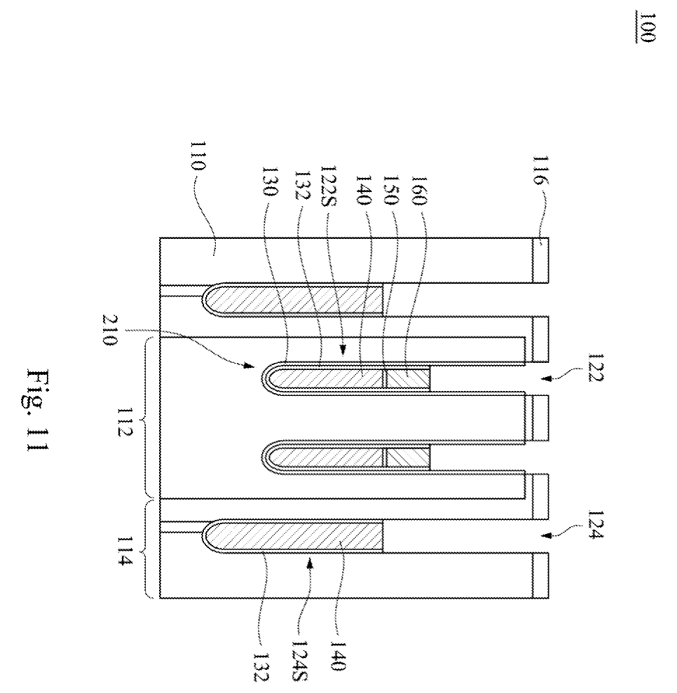

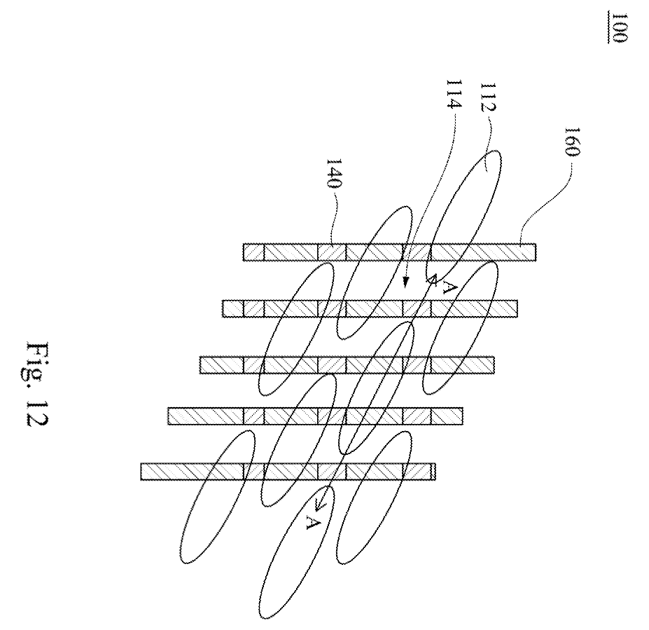

Referring to FIG. 11 and FIG. 12, FIG. 11 is a cross-sectional view schematic diagram along the A-A line in FIG. 12. In other words, FIG. 12 is a top view schematic diagram of FIG. 11. As shown in FIG. 11, the top conductive layer 160 in the second trench 124 is removed. In detail, the bottom dielectric layer 150 is also removed. After removing the top conductive layer 160 in the second trench 124, the photoresist layer 170 is stripped to expose the top conductive layer 160 in the first trench 122. As shown in FIG. 12, the top conductive layer 160 in the first trench 122 and the bottom conductive layer 140 are exposed.

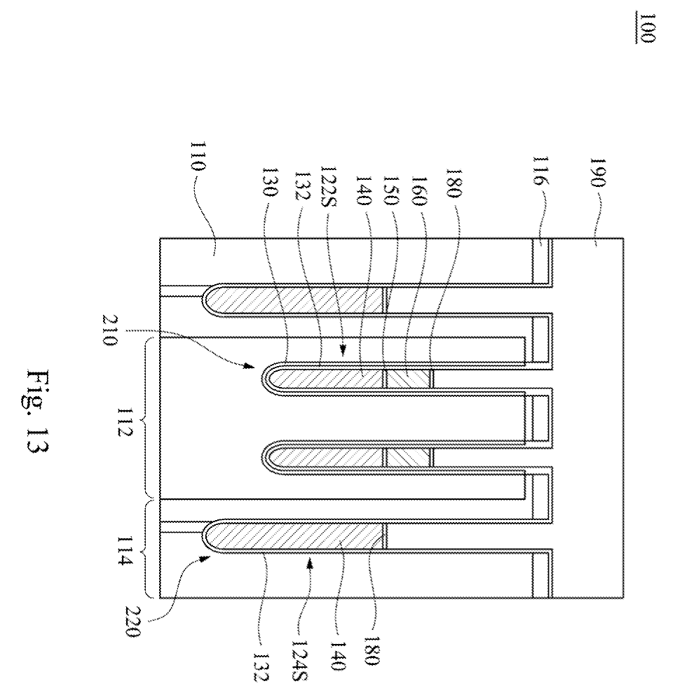

Referring to FIG. 13, a top dielectric layer 180 and a capping layer 190 are formed in the first trench 122 and the second trench 124. The top dielectric layer 180 may also cover the first sidewall 122S of the first trench 122, the second sidewall 124S of the second trench 124, and the top surface of the cover layer 116. The top dielectric layer 180 may be formed by atomic layer deposition (ALD) process. The top dielectric layer 180 may include oxide. In some embodiments, the top dielectric layer 180 may include same material with the oxidation layer 132. The first trench 122 and the second trench 124 are filled by the capping layer 190. The capping layer 190 is formed by suitable deposition process, for example, chemical vapor deposition (CVD), atomic layer deposition (ALD), or physical vapor deposition (PVD). The capping layer 190 may include nitride, for example silicon nitride (SiN).

As shown, a first word line structure 210 is formed in the active region 112 and a second word line structure 220 is formed in the isolation region 114. A bottom surface of the first word line structure 210 is higher than a bottom surface of the second word line structure 220. A top surface of the first word line structure 210 is higher than a top surface of the second word line structure 220. A top surface of the bottom conductive layer 140 of the first word line structure 210 and a top surface of the bottom conductive layer 140 of the second word line structure 220 are on the same level. The first word line structure 210 disposed in the active region 112 can be used as active word line. The second word line structure 220 disposed in the isolation region 114 can be used as passing word line.

The present disclosure provides a semiconductor and a manufacturing method thereof. The top conductive layer of the second word line structure in the isolation region is removed. In other words, the poly-silicon of the passing word line in the isolation region is removed, which may improve the performance of semiconductor device in long parallel select test (LPST). Moreover, the active word line in the active region may remain dual work function feature and may improve GIDL issue.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A manufacturing method of a semiconductor device, comprising:
forming a first trench in an active region of a substrate and forming a second trench in an isolation region of the substrate, wherein a second depth of the second trench is deeper than a first depth of the first trench;
forming a bottom conductive layer in the first trench and the second trench;
forming a top conductive layer on the bottom conductive layer;
forming a photoresist layer in the first trench and on a top surface of the substrate, wherein the top conductive layer in the second trench is exposed;
removing the top conductive layer in the second trench; and
forming a capping layer to fill the first trench and the second trench.

2. The manufacturing method of a semiconductor device of claim 1, wherein prior to forming the bottom conductive layer further comprises:
forming a barrier layer on a first sidewall of the first trench.

3. The manufacturing method of a semiconductor device of claim 2, wherein subsequent to forming the barrier layer further comprises:
forming an oxidation layer on the barrier layer of the first trench and a second sidewall of the second trench.

4. The manufacturing method of a semiconductor device of claim 3, wherein prior to forming the top conductive layer further comprises:
cleaning a portion of the oxidation layer on the first sidewall of the first trench and the second sidewall of the second trench; and
forming a bottom dielectric layer on the bottom conductive layer, the first sidewall of the first trench and the second sidewall of the second trench.

5. The manufacturing method of a semiconductor device of claim 3, wherein prior to forming the capping layer further comprises:
forming a top dielectric layer on the top conductive layer, the first sidewall of the first trench and the second sidewall of the second trench.

6. The manufacturing method of a semiconductor device of claim 1, wherein the photoresist layer is formed by a pitch doubling process.

7. The manufacturing method of a semiconductor device of claim 1, wherein prior to forming the first trench and the second trench further comprises:
forming a cover layer on the substrate.

8. The manufacturing method of a semiconductor device of claim 1, wherein prior to forming the capping layer further comprises:
stripping the photoresist layer to expose the top conductive layer in the first trench.

9. A semiconductor device, comprising:
a substrate having an active region and an isolation region;
a first word line structure disposed in the active region;
a second word line structure disposed in the isolation region; and
a capping layer disposed on the first word line structure, second word line structure and the substrate;
wherein a bottom surface of the first word line structure is higher than a bottom surface of the second word line structure; and
wherein a top surface of the first word line structure is higher than a top surface of the second word line structure.

10. The semiconductor device of claim 9, wherein the first word line structure comprises:
a bottom conductive layer; and
a top conductive layer on the bottom conductive layer; and
a bottom dielectric layer between the bottom conductive layer and the top conductive layer.

11. The semiconductor device of claim 10, wherein the second word line structure comprises a bottom conductive layer.

12. The semiconductor device of claim 11, wherein a top surface of the bottom conductive layer of the first word line structure and a top surface of the bottom conductive layer of the second word line structure are on the same level.

13. The semiconductor device of claim 11, further comprising:
a top dielectric layer between the top conductive layer of the first word line structure and the capping layer, and between the bottom conductive layer of the second word line structure and the capping layer, respectively.

14. The semiconductor device of claim 11, further comprising:
an oxidation layer between the substrate and the bottom conductive layer of the first word line structure, and between the substrate and the bottom conductive layer of the second word line structure.

15. The semiconductor device of claim 14, further comprising:
a barrier layer between the bottom conductive layer of the first word line structure and the oxidation layer.
